(19) United States
(12) Patent Application Publication
(10) Pub. No.: US 2026/0130095 A1
(43) Pub. Date: May 7, 2026

(54) DISPLAY DEVICE AND ELECTRONIC DEVICE

(71) Applicant: Samsung Display Co., Ltd., Yongin-si (KR)

(72) Inventors: Oh June KWON, Yongin-si (KR); Dae Il KIM, Yongin-si (KR); Woo Yong SUNG, Yongin-si (KR)

(21) Appl. No.: 19/268,486

(22) Filed: Jul. 14, 2025

(30) Foreign Application Priority Data
Nov. 4, 2024 (KR) 10-2024-0154360

(51) Int. Cl. H10K 59/80; H10K 59/124

(52) U.S. Cl. CPC H10K 59/873; H10K 59/124

(57) ABSTRACT

A display device includes: a substrate; a transistor layer on an upper surface of the substrate; a display element layer on the transistor layer; an encapsulation layer on the display element layer; a polarizing layer on the encapsulation layer; a substrate cover layer on a lower surface of the substrate; and a through hole penetrating the substrate cover layer, the substrate, the transistor layer, the display element layer, the encapsulation layer, and the polarizing layer in a display area of the substrate, wherein a thickness of the substrate cover layer is constant throughout an entire area of the substrate cover layer.

### CROSS-REFERENCE TO RELATED APPLICATION

The present application claims priority to and the benefit of Korean Patent Application No. 10-2024-0154360, filed on Nov. 4, 2024, in the Korean Intellectual Property Office, the entire disclosure of which is incorporated herein by reference.

### BACKGROUND

### 1. Field

Aspects of some embodiments of the present disclosure relate to a display device.

### 2. Description of the Related Art

In order to provide image information, a variety of types of electronic devices, including display modules, are being used. Such an electronic device may include an electronic module that receives an external signal or provides an output signal to the outside. For example, an electronic module may include a camera module, etc. There is an increasing demand for display devices that can capture high-quality images.

The above information disclosed in this Background section is only for enhancement of understanding of the background and therefore the information discussed in this Background section does not necessarily constitute prior art.

### SUMMARY

Aspects of some embodiments of the present disclosure relate to a display device, and for example to a display device that can maintain a constant efficiency of blocking light throughout the entire area of a substrate, and an electronic device including the same.

Aspects of some embodiments of the present disclosure include a display device that can maintain a constant efficiency of blocking light throughout the entire area of a substrate, and an electronic device including the same.

According to some embodiments of the present disclosure, there is provided a display device including: a substrate; a transistor layer on an upper surface of the substrate; a display element layer on the transistor layer; an encapsulation layer on the display element layer; a polarizing layer on the encapsulation layer; a substrate cover layer on a lower surface of the substrate; and a through hole penetrating the substrate cover layer, the substrate, the transistor layer, the display element layer, the encapsulation layer, and the polarizing layer in a display area of the substrate. According to some embodiments, the thickness of the substrate cover layer may be constant (or substantially constant) throughout an entire area of the substrate cover layer.

According to some embodiments of the present disclosure, there is provided a display device including: a substrate; a transistor layer on an upper surface of the substrate; a display element layer on the transistor layer; an encapsulation layer on the display element layer; a polarizing layer on the encapsulation layer; a substrate cover layer on a lower surface of the substrate; and a through hole penetrating the substrate cover layer, the substrate, the transistor layer, the display element layer, the encapsulation layer, and the polarizing layer in a display area of the substrate. According to some embodiments, the substrate cover layer may include: an upper surface in contact with the lower surface of the substrate; a lower surface opposite the upper surface of the substrate cover layer; and an inner surface defining an inner wall of the through hole. According to some embodiments, the inclination of the inner surface of the substrate cover layer may be different from the inclination of the lower surface of the substrate cover layer.

According to some embodiments of the present disclosure, there is provided an electronic device including: a display device providing a screen. According to some embodiments, the display device may include a substrate; a transistor layer on an upper surface of the substrate; a display element layer on the transistor layer; an encapsulation layer on the display element layer; a polarizing layer on the encapsulation layer; a substrate cover layer on a lower surface of the substrate; and a through hole penetrating the substrate cover layer, the substrate, the transistor layer, the display element layer, the encapsulation layer, and the polarizing layer in a display area of the substrate. According to some embodiments, the thickness of the substrate cover layer may be constant (or substantially constant) throughout an entire area of the substrate cover layer.

According to some embodiments of the present disclosure, it may be possible to achieve a constant efficiency of blocking light throughout the entire substrate of a display device. For example, according to some embodiments, because the thickness of a substrate cover layer is maintained to be uniform (or substantially uniform over the entire area of the substrate cover layer, the efficiency of blocking light can be maintained uniformly throughout the entire area of the substrate. Accordingly, according to some embodiments, the image quality of the display device and electronic device may be relatively improved.

The characteristics of embodiments according to the present disclosure are not limited to the above-described characteristics and other characteristics which are not described herein will become apparent to those skilled in the art from the following description.

### BRIEF DESCRIPTION OF THE DRAWINGS

The above and other aspects and features of the present disclosure will become more apparent by describing in more detail aspects of some embodiments thereof with reference to the attached drawings, in which:

FIG. 1 is a perspective view of a display device according to some embodiments of the present disclosure.

FIG. 2 is a plan view showing a display panel according to some embodiments of the present disclosure.

FIG. 3 is a cross-sectional view showing an example of the display device taken along the line I-I′ of FIG. 1.

FIG. 4 is a cross-sectional view showing an example of the display pixel of FIG. 3 when the circuit board is bent.

FIG. 5 is a cross-sectional view of a part of a display device according to some embodiments of the present disclosure.

FIG. 6 is a cross-sectional view of a part of a display device according to some embodiments of the present disclosure.

FIG. 7 is an enlarged view of area B of FIG. 6.

FIG. 8 is a cross-sectional view of a part of a display device according to some embodiments of the present disclosure.

FIG. 9 is a cross-sectional view of a part of a display device according to some embodiments of the present disclosure.

FIG. 10 is a cross-sectional view of a display device according to some embodiments of the present disclosure.

FIG. 11 is a cross-sectional view of a part of a display device according to some embodiments of the present disclosure.

FIG. 12 is a cross-sectional view of a part of a display device according to some embodiments of the present disclosure.

FIG. 13, FIG. 14, FIG. 15, FIG. 16, FIG. 17, FIG. 18, FIG. 19, FIG. 20, FIG. 21, FIG. 22 and FIG. 23 are cross-sectional views for illustrating processor steps of a method for fabricating a display device according to some embodiments.

FIG. 24 is a view showing a dummy hole, a first sub-through hole, a substrate, and a substrate cover layer according to some embodiments.

FIG. 25 is a view showing a third sub-through hole, a first sub-through hole, a substrate, and a substrate cover layer according to some embodiments.

FIGS. 26 to 28 are cross-sectional views showing processing steps for illustrating a method for fabricating a display device according to some embodiments of the present disclosure.

FIGS. 29 to 32 are cross-sectional views showing processing steps for illustrating a method for fabricating a display device according to some embodiments of the present disclosure.

FIG. 33 is a perspective view showing an electronic device employing a display device according to some embodiments.

FIG. 34 is a block diagram of an electronic device according to some embodiments.

FIGS. 35, 36 and 37 are schematic diagrams of electronic devices according to various embodiments.

### DETAILED DESCRIPTION

The present invention will now be described more fully hereinafter with reference to the accompanying drawings, in which aspects of some embodiments of the present disclosure are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, aspects of some embodiments will be described with reference to the accompanying drawings.

Hereinafter, aspects of some embodiments of the present disclosure will be described in more detail with reference to the accompanying drawings.

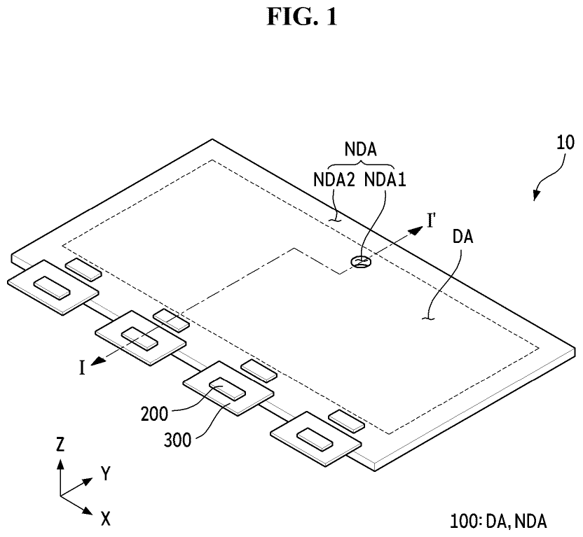

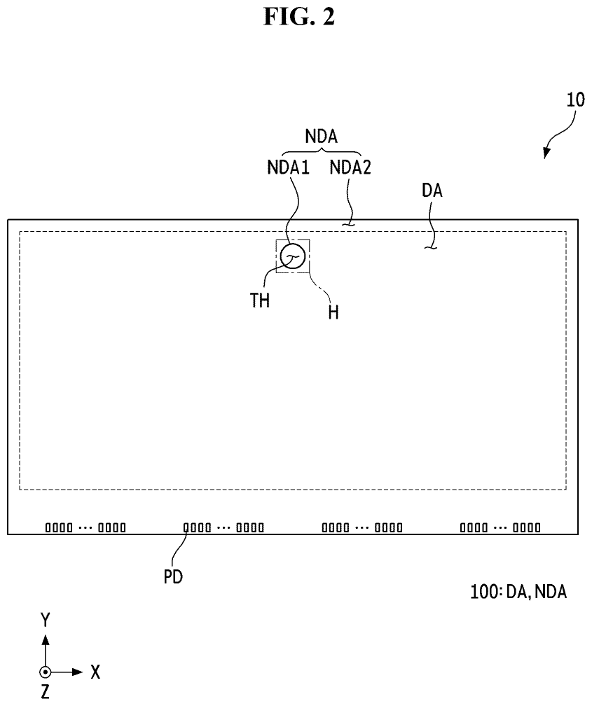

FIG. 1 is a perspective view of a display device according to some embodiments of the present disclosure. FIG. 2 is a plan view showing a display panel according to some embodiments of the present disclosure.

Referring to FIG. 1, a display device 10 according to some embodiments of the present disclosure is for displaying moving images or still images. The display device 10 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things (IoT) devices.

According to some embodiments of the present disclosure, the display device 10 may be a light-emitting display device such as an organic light-emitting display device using organic light-emitting diodes, a quantum-dot light-emitting display device including quantum-dot light-emitting layer, an inorganic light-emitting display device including an inorganic semiconductor, and a micro-LED display device using micro or nano light-emitting diodes (micro LEDs or nano LEDs). In the following description, an organic light-emitting display device is described as an example of the display device 10. It is, however, to be understood that the present disclosure is not limited thereto.

The display device 10 according to some embodiments may include a display panel 100, a display driver 200 and a circuit board 300.

The display panel 100 may be formed in a rectangular plane having longer sides in a first direction (x-axis direction) and shorter sides in a second direction (y-axis direction) intersecting the first direction (x-axis direction). Each of the corners where the longer side in the first direction (x-axis direction) meets the shorter side in the second direction (y-axis direction) may be formed at a right angle or may be rounded with a curvature. The shape of the display panel 100 when viewed from the top (e.g., in a plan view) is not limited to a quadrangular shape, but may be formed in a different polygonal shape, a circular shape, or an elliptical shape.

The display panel 100 may be formed flat, but the present disclosure is not limited thereto. For example, the display panel 100 may be formed at left and right ends, and may include a curved portion having a constant curvature or a varying curvature. In addition, the display panel 100 may be flexible so that it can be curved, bent, folded or rolled.

The display panel 100 may include a display area DA where images are displayed, and a non-display area NDA where no images are displayed.

The display area DA may occupy most of the area of the display panel 100. The display area DA may be located at the center of display device 100. In the display area DA, pixels each including a plurality of emission areas may be arranged to display images.

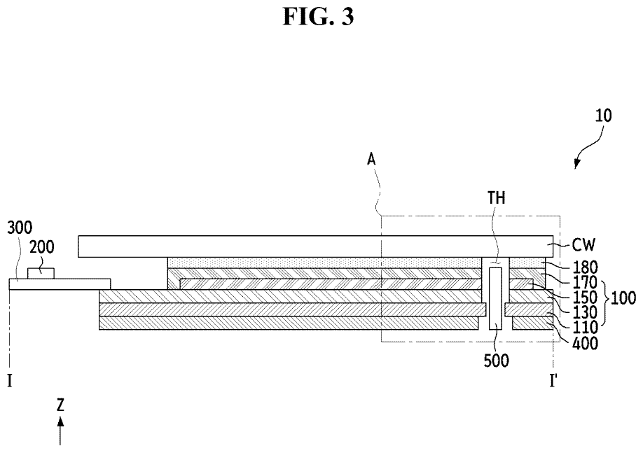

The non-display area NDA may include a first non-display area NDA1 and a second non-display area NDA2. The first non-display area NDA1 may be located on a side of the display area DA (e.g., surrounded by or within a footprint of the display area DA). The first non-display area NDA1 may surround the through hole TH. The through hole TH may be a hole that allows light to transmit it and may be an area where an optical module 500 (see FIG. 3) is located.

The second non-display area NDA2 may be located adjacent to (e.g., in a periphery or outside a footprint of) the display area DA. The second non-display area NDA2 may be on the outer side of the display area DA. The second non-display area NDA2 may be arranged to surround the display area DA. The second non-display area NDA2 may be an edge area of the display panel 100.

Referring to FIGS. 1 and 2, the second non-display area NDA2 may include display pads PD, display drivers 200 and circuit boards 300.

The display pads PD may be located at one edge of the display panel 100. For example, the display pads PD may be located at the lower edge of the display panel 100. The display pads PD may be connected to the display drivers 200 and the circuit boards 300.

The display drivers 200 may generate and output signals and voltages for driving the display panel 100. For example, the display drivers 200 may generate and output data voltages, supply voltages, scan timing signals, etc. The display driver 200 may apply a supply voltage to a voltage line and may supply gate control signals to the gate driver.

The display drivers 200 may be located on the circuit boards 300, respectively. For example, the display drivers 200 may be respectively arranged on the circuit boards by the chip-on-film (COF) technique.

The circuit boards 300 may be located at an edge of the display panel 100. The circuit boards 300 may be located on the display pads PD at an edge of the display panel 100. The circuit boards 300 may be attached to the display pads PD using a conductive adhesive member such as an anisotropic conductive film and an anisotropic conductive adhesive. Accordingly, the circuit boards 300 may be electrically connected to signal lines of the display panel 100. The circuit boards 300 may be flexible printed circuit boards, flexible films such as chip on films.

According to some embodiments, a bending area BA may be located between the display drivers 200 and the display area DA in the second non-display area NDA2. The bending area BA may be bent such that the display drivers 200 and the circuit boards 300 are located under the display panel 100. The display drivers 200 and the circuit boards 300 bent at the bending area BA may overlap the display area DA in the third direction (z-axis direction).

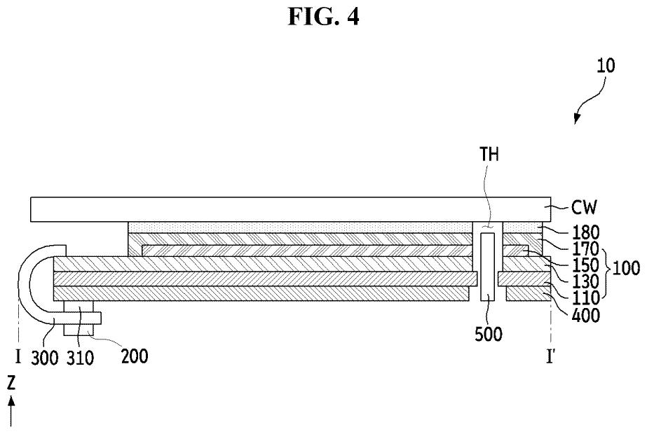

FIG. 3 is a cross-sectional view showing an example of the display device taken along the line I-I′ of FIG. 1. FIG. 4 is a cross-sectional view showing an example of the display pixel of FIG. 3 when the circuit board is bent.

Referring to FIG. 3, the display device 10 according to some embodiments may include the display panel 100, a polarizing plate 180, a cover window CW and a substrate cover layer 400. The display panel 100 may include a substrate 110, a transistor layer 130, a display element layer 150, an encapsulation layer 170.

The substrate 110 may be a base substrate or a base member. The substrate 110 may be a flexible substrate that can be bent, folded, or rolled. For example, the substrate 110 may include, but is not limited to, a polymer resin such as polyimide PI. According to some embodiments, the substrate 110 may include a glass material or a metal material.

The transistor layer 130 may be located on the substrate 110. The transistor layer 130 may include a plurality of transistors. Each of the transistors may include a semiconductor region, a source electrode, a drain electrode, and a gate electrode.

The display element layer 150 may be located on the transistor layer 130. The display element layer 150 may include a plurality of light-emitting elements each including a pixel electrode, a common electrode and an emissive layer to emit light, and a pixel-defining film for defining the pixels. The plurality of light-emitting elements may be located in the display area DA.

The encapsulation layer 170 may be located on the display element layer 150. The encapsulation layer 170 may cover the upper and side surfaces of the display element layer 150 in order to prevent or reduce permeation of contaminants such as oxygen or moisture into the display element layer 150. The encapsulation layer 170 may include at least one inorganic film and at least one organic film.

The polarizing plate 180 may be located on the encapsulation layer 170. The polarizing plate 180 may be located on the display panel 100 in order to reduce reflection of external light. The polarizing plate 180 may include a first base member, a linear polarizer, a retardation film such as a λ/4 (quarter-wave) plate, and a second base member. The first base member, the retardation film, the linear polarizer and the second base member of the polarizing plate 180 may be sequentially stacked on the display panel 100.

The cover window CW may be located on the polarizing plate 180. The cover window CW may be attached onto the polarizing plate 180 by a transparent adhesive member such as an optically clear adhesive (OCA) film.

The substrate cover layer 400 may be located on the lower surface of the substrate 110. The lower surface of the substrate 110 may be opposite to the upper surface. In other words, the lower surface of the substrate 110 may be the opposite surface of the surface where the transistor layer 130, the display element layer 150, the encapsulation layer 170 and the polarizing plate 180 are positioned. The substrate cover layer 400 may protect the lower surface of the substrate 110 and may also work as a shielding layer that blocks light incident on the lower surface of the substrate. The substrate cover layer 400 may be made of a material containing a black pigment. The substrate cover layer 400 may be attached to the lower surface of the substrate 110 through an adhesive member. The adhesive member may be a pressure-sensitive adhesive (PSA).

In some embodiments, the display device 10 may further include an optical module 500. The optical module 500 may output or receive light in infrared, ultraviolet, and visible ranges. For example, the optical module 500 may include an optical sensor that senses light incident on the display device 10, such as a proximity sensor, an illuminance sensor, a camera sensor and an image sensor.

The optical module 500 may be located in the through hole TH. The through hole TH may allow light to pass through it, and may be a physical hole penetrating through the substrate cover layer 400, the display panel 100 and the polarizing plate 180. It should be understood, however, that the present disclosure is not limited thereto. The through hole TH may penetrate through the substrate cover layer 400 but may not penetrate through the display panel 100 or the polarizing film 180. The cover window CW may be arranged to cover the through hole TH.

The through hole may have a circular shape in a plan view as shown in FIG. 2. It should be understood, however, that the embodiments of the present disclosure are not limited thereto. The shape of the through hole may be modified in a variety of ways.

Referring to FIG. 4, the display drivers 200 and the circuit boards 300 may be bent such that they are located under the display panel 100. The circuit boards 300 may be attached to the lower surface of the substrate cover layer 400 by an adhesive member 310. The adhesive member 310 may be a pressure-sensitive adhesive.

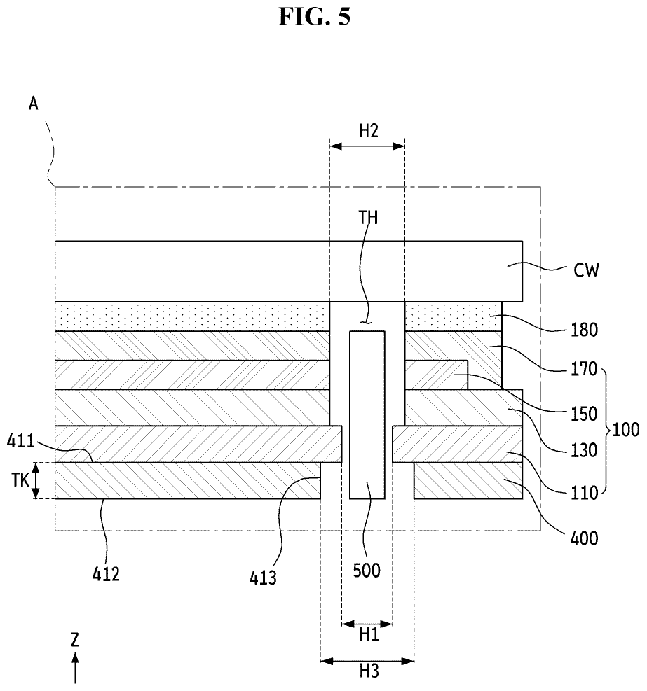

FIG. 5 is a cross-sectional view of a part of the display device 10 according to some embodiments of the present disclosure. For example, FIG. 5 may be an enlarged view of area A of FIG. 3.

As shown in FIG. 5, the through hole TH may penetrate the substrate cover layer 400, the substrate 110, the transistor layer 130, the display element layer 150, the encapsulation layer 170, and the polarizing plate 180. In the cross-sectional view as shown in FIG. 5, the through hole TH may have different diameters along the longitudinal direction of the through hole TH. For example, the through hole TH may include a first sub-through hole H1, a second sub-through hole H2, and a third sub-through hole H3 having different diameters.

The first sub-through hole H1, the second sub-through hole H2 and the third sub-through hole H3 may overlap one another along the third direction.

The first sub-through hole H1 may penetrate the substrate 110.

The second sub-through hole H2 may penetrate the transistor layer 130, the display element layer 150, the encapsulation layer 170 and the polarizing plate 180. The diameter of the second sub-through hole H2 may be larger than the diameter of the first sub-through hole H1. When viewed from the top, the circumference (or inner wall) of the second sub-through hole H2 may surround the first sub-through hole H1.

The third sub-through hole H3 may penetrate the substrate cover layer 400. The diameter of the third sub-through hole H3 may be greater than the diameter of the second sub-through hole H2. When viewed from the top, the circumference (or inner wall) of the third sub-through hole H3 may surround the first sub-through hole H1 and the second sub-through hole H2.

The substrate cover layer 400 defining the third sub-through hole H3 may have a uniform thickness TK on the substrate 110. For example, the thickness TK of the substrate cover layer 400 may be uniform (or substantially uniform) throughout the entire substrate cover layer 400. In other words, the distance from the lower surface of the substrate 110 to the lower surface 412 of the substrate cover layer 400 may be constant over the entire area of the substrate cover layer 400. Herein, the thickness TK of the substrate cover layer 400 may be the size of the substrate cover layer 400 in the third direction. According to some embodiments, the upper surface 411 and the lower surface 412 of the substrate cover layer 400 may be parallel to each other. The upper surface 411 of the substrate cover layer 400 may come into contact with the lower surface of the substrate 110. The lower surface 412 of the substrate cover layer 400 may be opposed to the upper surface 411 of the substrate cover layer 400.

The inner wall of the third sub-through hole H3 may be defined by an inner surface 413 of the substrate cover layer 400, and the angle formed by the inner surface 413 of the substrate cover layer 400 and the upper surface 411 of the substrate cover layer 400 may be equal to 90 degrees. In addition, the angle formed by the inner surface 413 of the substrate cover layer 400 and the lower surface 412 of the substrate cover layer 400 may be 90 degrees.

According to some embodiments, because the substrate cover layer 400 has a uniform thickness TK over the entire area, the efficiency of blocking light can be uniform throughout the entire display device 10 (e.g., the entire areas of the substrate 110). Accordingly, the image quality of the display device 10 can be relatively improved.

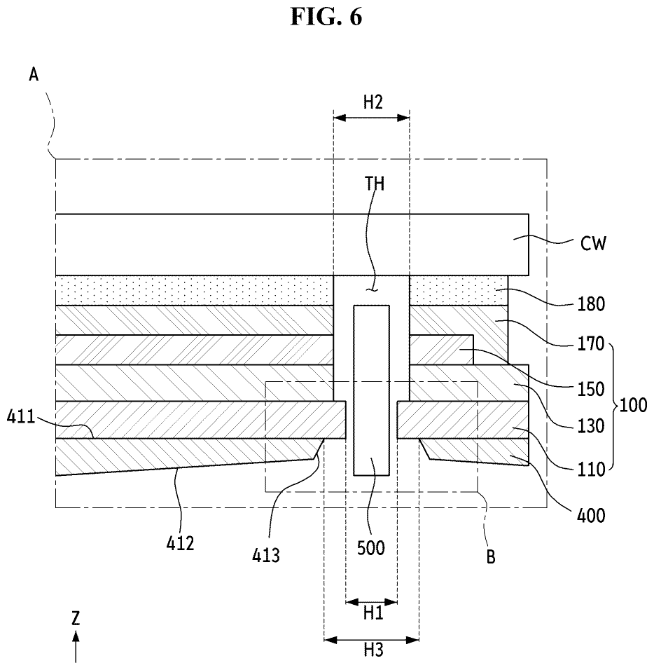

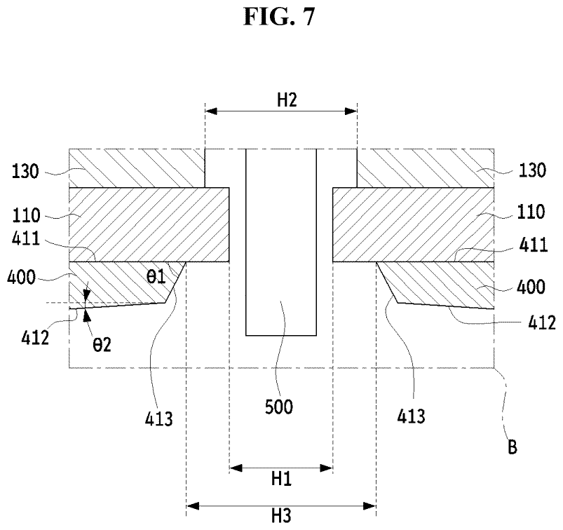

FIG. 6 is a cross-sectional view of a part of a display device 10 according to some embodiments of the present disclosure. For example, FIG. 6 may be another enlarged view of area A of FIG. 3. FIG. 7 is an enlarged view of area B of FIG. 6.

A display device 10 of FIGS. 6 and 7 is different from the above-described display device 10 of FIG. 5 in a shape of the substrate cover layer 400. The following description will focus on the difference.

As shown in FIGS. 6 and 7, the substrate cover layer 400 may have a thickness that gradually decreases toward a through hole TH. The lower surface 412 and the inner surface 413 of the substrate cover layer 400 may each have an obliquely inclined shape. The inclination of the lower surface 412 of the substrate cover layer 400 may be different from the inclination of the inner surface 413 of the substrate cover layer 400. For example, the inclination of the inner surface 413 with respect to the upper surface 411 of the substrate cover layer 400 may be greater than the inclination of the lower surface 412 with respect to the upper surface 411 of the substrate cover layer 400. In other words, the internal angle θ1 between the upper surface 411 and the inner surface 413 of the substrate cover layer 400 may be greater than the internal angle θ2 between the upper surface 411 and the lower surface 412 of the substrate cover layer 400.

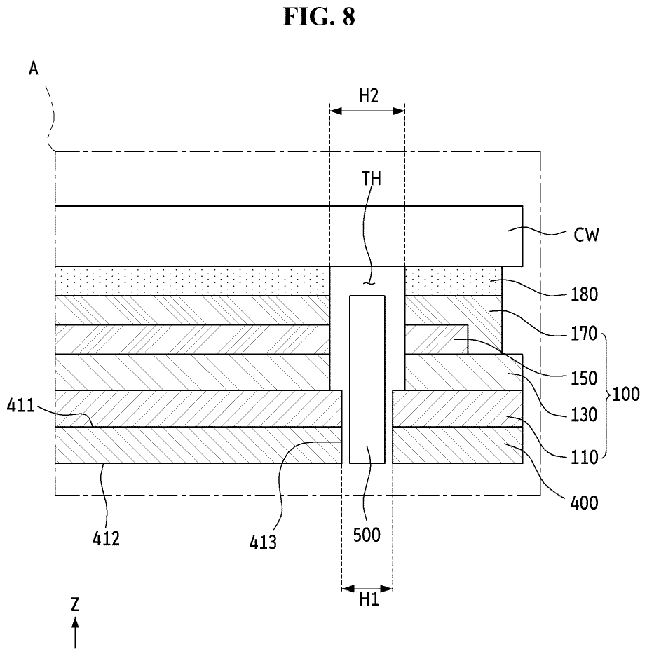

FIG. 8 is a cross-sectional view of a part of a display device 10 according to some embodiments of the present disclosure. For example, FIG. 8 may be another enlarged view of area A of FIG. 3.

A display device 10 of FIG. 8 is different from the above-described display device 10 of FIG. 5 in a shape of the substrate cover layer 400. The following description will focus on the difference.

As shown in FIG. 8, a through hole TH may include a first sub-through hole H1 and a second sub-through hole H2 having different diameters.

The first sub-through hole H1 and the second sub-through hole H2 may overlap each other along the third direction.

The first sub-through hole H1 may penetrate the substrate 110 and the substrate cover layer 400. For example, the diameter of the hole penetrating the substrate 110 may be equal to the diameter of the hole penetrating the substrate cover layer 400.

The second sub-through hole H2 may penetrate the transistor layer 130, the display element layer 150, the encapsulation layer 170 and the polarizing plate 180. The diameter of the second sub-through hole H2 may be larger than the diameter of the first sub-through hole H1. When viewed from the top, the circumference (or inner wall) of the second sub-through hole H2 may surround the first sub-through hole H1.

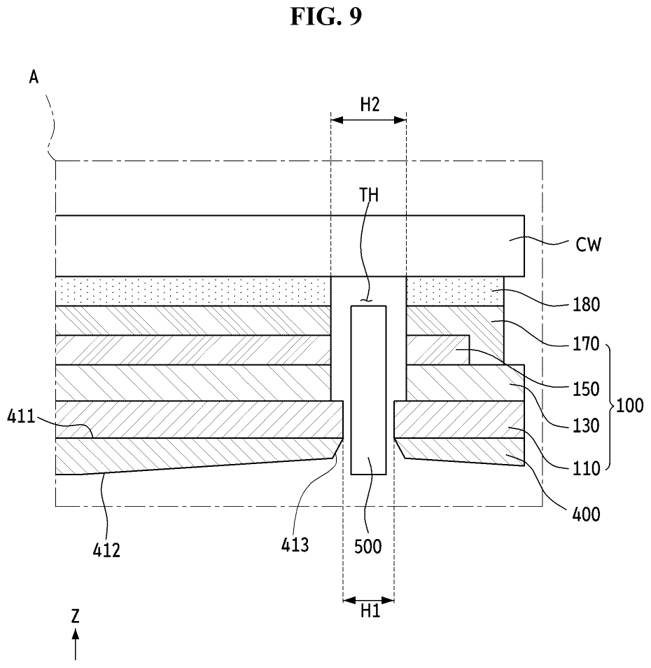

FIG. 9 is a cross-sectional view of a part of a display device 10 according to some embodiments of the present disclosure. For example, FIG. 9 may be another enlarged view of area A of FIG. 3.

A display device 10 of FIG. 9 is different from the above-described display device 10 of FIG. 6 in a shape of the substrate cover layer 400. The following description will focus on the difference.

As shown in FIG. 9, a through hole TH may include a first sub-through hole H1 and a second sub-through hole H2 having different diameters.

The first sub-through hole H1 and the second sub-through hole H2 may overlap each other along the third direction.

The first sub-through hole H1 may penetrate the substrate 110 and the substrate cover layer 400. For example, the diameter of the hole penetrating the substrate 110 may be equal to the diameter of the hole penetrating the substrate cover layer 400.

The second sub-through hole H2 may penetrate the transistor layer 130, the display element layer 150, the encapsulation layer 170 and the polarizing plate 180. The diameter of the second sub-through hole H2 may be larger than the diameter of the first sub-through hole H1. When viewed from the top, the circumference (or inner wall) of the second sub-through hole H2 may surround the first sub-through hole H1.

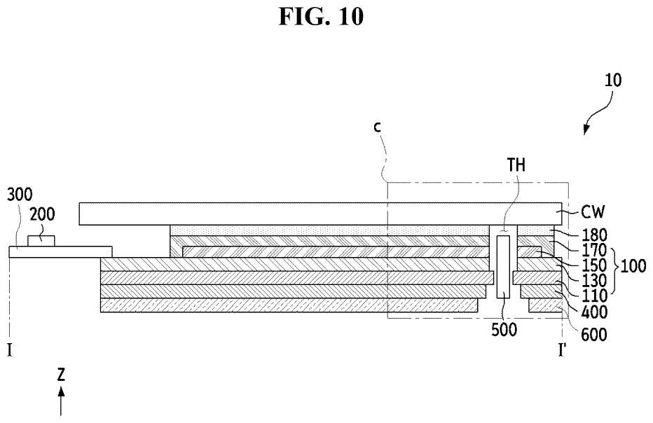

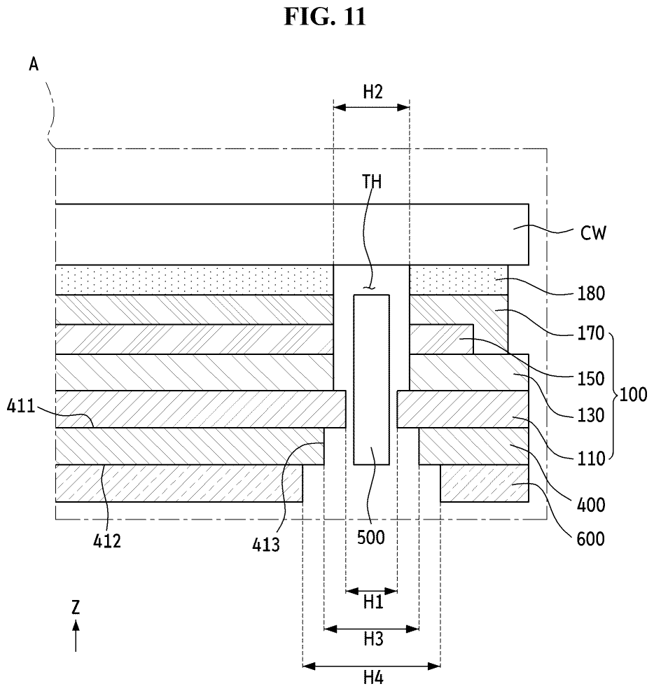

FIG. 10 is a cross-sectional view of a display device 10 according to some embodiments of the present disclosure. FIG. 11 is a cross-sectional view of a part of a display device 10 according to some embodiments of the present disclosure. For example, FIG. 11 may be an enlarged view of area C of FIG. 10.

A display device 10 of FIGS. 10 and 11 is different from the above-described display device 10 of FIG. 3 in that the former further includes a functional layer 600. The following description will focus on the difference.

As shown in FIG. 10 and FIG. 11, the display device 10 may further include the functional layer 600. The functional layer 600 may include at least one of a shock-absorbing member for absorbing shock from the outside, or a heat dissipation member for efficiently discharging heat.

The functional layer 600 may be located on the lower surface of the substrate cover layer 400. Accordingly, the substrate cover layer 400 may be located between the substrate 110 and the functional layer 600.

As shown in FIGS. 10 and 11, a through hole TH may penetrate the functional layer 600, a substrate cover layer 400, a substrate 110, a transistor layer 130, a display element layer 150, an encapsulation layer 170, and a polarizing plate 180. In the cross-sectional view as shown in FIG. 11, the through hole TH may have different diameters along the longitudinal direction of the through hole TH. For example, the through hole TH may include a first sub-through hole H1, a second sub-through hole H2, a third sub-through hole H3 and a fourth sub-through hole H4 having different diameters.

The first sub-through hole H1, the second sub-through hole H2, the third sub-through hole H3 and the fourth sub-through hole H4 may overlap one another along the third direction.

The first sub-through hole H1 may penetrate the substrate 110.

The second sub-through hole H2 may penetrate the transistor layer 130, the display element layer 150, the encapsulation layer 170 and the polarizing plate 180. The diameter of the second sub-through hole H2 may be larger than the diameter of the first sub-through hole H1. When viewed from the top, the circumference (or inner wall) of the second sub-through hole H2 may surround the first sub-through hole H1.

The third sub-through hole H3 may penetrate the substrate cover layer 400. The diameter of the third sub-through hole H3 may be greater than the diameter of the second sub-through hole H2. When viewed from the top, the circumference (or inner wall) of the third sub-through hole H3 may surround the first sub-through hole H1 and the second sub-through hole H2.

A fourth sub-through hole TH may penetrate the functional layer 600. The diameter of the fourth sub-through hole H4 may be larger than the diameter of the third sub-through hole H3. When viewed from the top, the circumference (or inner wall) of the fourth sub-through hole H4 may surround the first sub-through hole H1, the second sub-through hole H2 and the third sub-through hole H3.

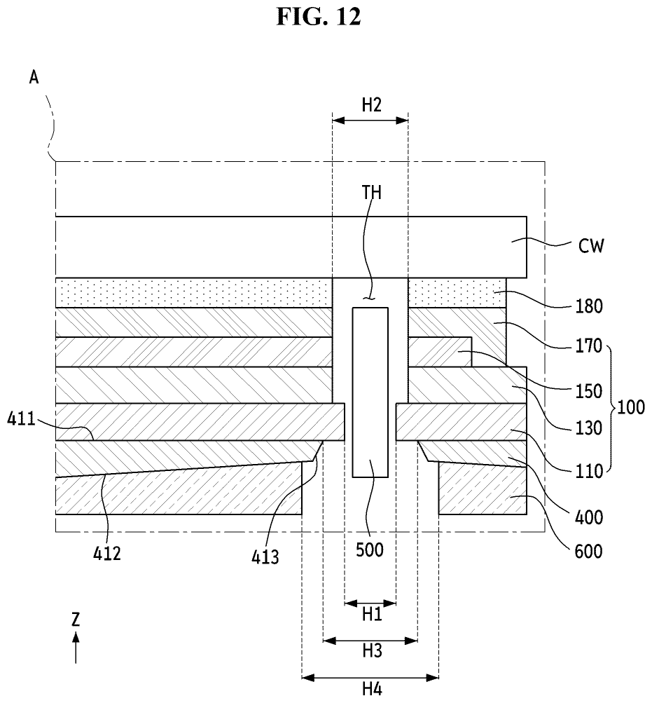

FIG. 12 is a cross-sectional view of a part of a display device 10 according to some embodiments of the present disclosure. For example, FIG. 12 may be an enlarged view of area C of FIG. 10.

A display device 10 of FIG. 12 is different from the above-described display device 10 of FIG. 11 in a shape of the substrate cover layer 400. The following description will focus on the difference.

As shown in FIG. 12, the substrate cover layer 400 may have the same shape as the substrate cover layer 400 of FIG. 6 described above. The substrate cover layer 400 of FIG. 12 is identical to that described above with reference to FIG. 6; and, therefore, the redundant descriptions will be omitted.

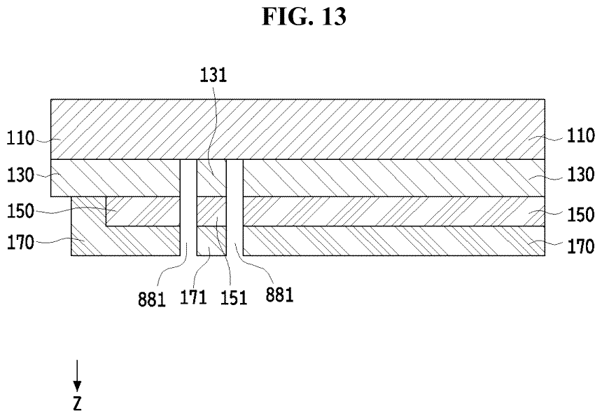

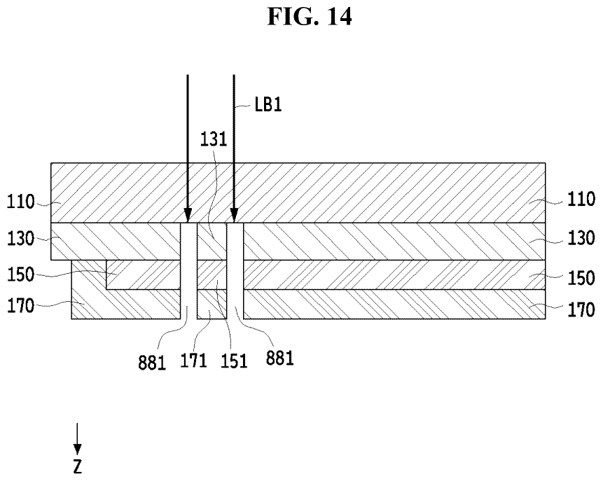

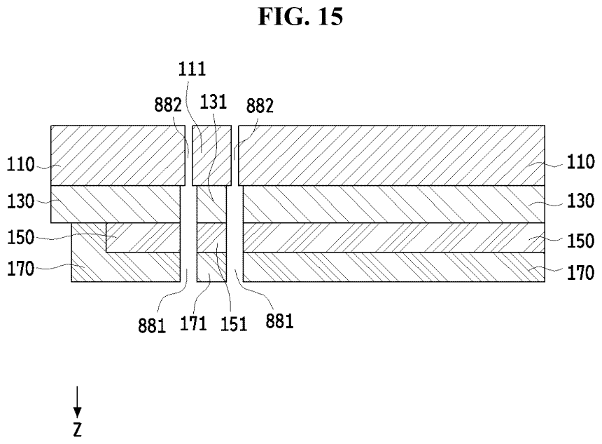

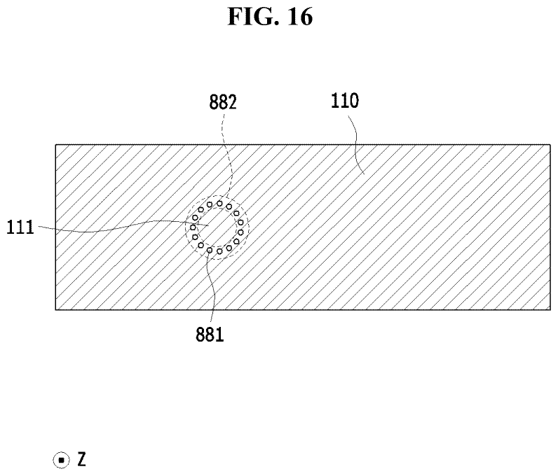

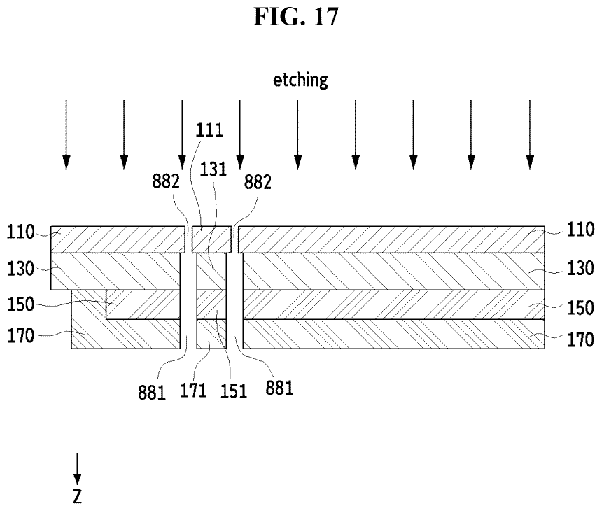

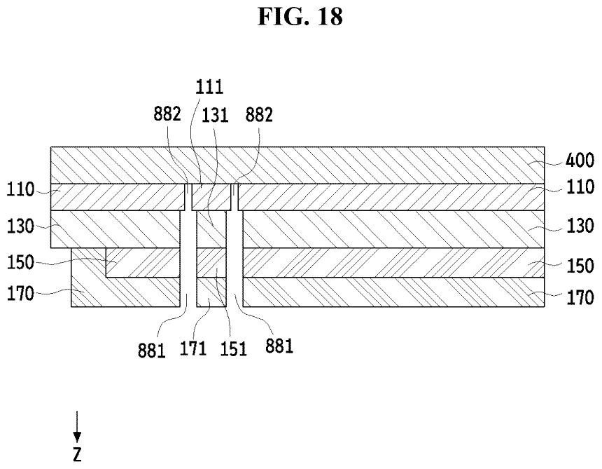

FIG. 13, FIG. 14, FIG. 15, FIG. 16, FIG. 17, FIG. 18, FIG. 19, FIG. 20, FIG. 21, FIG. 22 and FIG. 23 are cross-sectional views for illustrating processor steps of a method for fabricating a display device 10 according to some embodiments. For example, FIGS. 13 to 23 may be cross-sectional views for illustrating processing steps for fabricating the display device 10 of FIG. 5 described above. FIG. 16 is a plan view of the substrate 110 of FIG. 15 as viewed from below the substrate 110. FIG. 20 is a plan view of the substrate cover layer 400 of FIG. 19 as viewed from below the substrate cover layer 400. FIG. 23 is a plan view of the substrate cover layer 400 of FIG. 22 as viewed from below the substrate cover layer 400.

The substrate 110 in FIGS. 13 to 23 may be turned over such that the lower surface of the substrate 110 faces upward for the process.

Initially, as shown in FIG. 13, a substrate 110 having a transistor layer 130, a display element layer 150 and an encapsulation layer 170 located thereon may be prepared. The transistor layer 130, the display element layer 150 and the encapsulation layer 170 may be located on the upper surface of the substrate 110. The transistor layer 130, the display element layer 150 and the encapsulation layer 170 may be cut at a position of a through hole TH to be described later. For example, the transistor layer 130, the display element layer 150 and the encapsulation layer 170 may be cut at a position of the through hole TH to be described later by a first cut hole 881. By the first cut hole 881, a dummy transistor layer 131, a dummy display element layer 151, and a dummy encapsulation layer 171 may be located at the position of the through hole TH. By the first cut hole 881, the dummy transistor layer 131, the dummy display element layer 151 and the dummy encapsulation layer 171 may be separated from the transistor layer 130, the display element layer 150 and the encapsulation layer 170, respectively. When viewed from the top, the first cut hole 881 may have a shape of a closed curve surrounding the dummy transistor layer 131, the dummy display element layer 151 and the dummy encapsulation layer 171 (see the first cut hole 881 of FIG. 16). The first cut hole 881 may be formed by a laser beam. For example, the first cut hole 881 may be formed in the encapsulation layer 170, the display element layer 150 and the transistor layer 130 by irradiating the laser beam onto the encapsulation layer 170, the display element layer 150 and the transistor layer 130 from above the encapsulation layer 170.

Subsequently, as shown in FIG. 14, a laser beam LB1 may be irradiated onto the substrate 110 from the lower surface of the substrate 110. For example, the laser beam LB1 may be irradiated onto the lower surface of the substrate 110 in line with the first cut hole 881. In doing so, the laser beam may be irradiated onto the lower surface of the substrate 110 multiple times discontinuously along the first cut hole 881. Accordingly, as shown in FIGS. 15 and 16, a plurality of second cut holes 882 penetrating the substrate 110 may be formed along the first cut hole 881. The substrate 110 may be partially cut at the position of the through hole TH by the second cut holes 882. By virtue of the second cut holes 882, a dummy substrate 111 may be located at the position of the through hole TH. By virtue of the second cut holes 882, the substrate 110 and the dummy substrate 111 may be partially cut. Accordingly, the substrate 110 and the dummy substrate 111 may be weakly connected to each other. In the plan view as shown in FIG. 16, the plurality of second cut holes 882 may be arranged in a dot pattern around the dummy substrate 111. For example, the second cut holes 882 may have a shape of discontinuous cut holes arranged along the first cut hole 881 such that it overlaps with the first cut hole 881. The second cut holes 882 may be connected to the first cut hole 881.

Subsequently, as shown in FIG. 17, the lower surfaces of the substrate 110 and the dummy substrate 111 are etched, such that the thickness of each of the substrate 110 and the dummy substrate 111 may be reduced.

Subsequently, as shown in FIG. 18, a substrate cover layer 400 may be formed on the lower surfaces of the substrate 110 and the dummy substrate 111 to protect the lower surface of the etched substrate 110. For example, the substrate cover layer 400 may be formed by applying a raw material (e.g., resin) of the substrate cover layer 400 on the lower surfaces of the substrate 110 and the dummy substrate 111 by inkjet printing and then curing it. In doing so, the substrate cover layer 400 may be formed on the entire lower surfaces of the substrate 110 and the dummy substrate 111. For example, the substrate cover layer 400 may be formed on the substrate 110, the dummy substrate 111 and the plurality of second cut holes 882 to cover the substrate 110, the dummy substrate 111 and the plurality of second cut holes 882.

Subsequently, as shown in FIG. 19, the dummy substrate 111, the dummy transistor layer 131, the dummy display element layer 151 and the dummy encapsulation layer 171 may be eliminated. For example, the dummy substrate 111, the dummy transistor layer 131, the dummy display element layer 151 and the dummy encapsulation layer 171 may be removed by adsorbing the dummy transistor layer 131, the dummy display element layer 151 and the dummy encapsulation layer 171 using an adsorption device. After the dummy substrate 111, the dummy transistor layer 131, the dummy display element layer 151 and the dummy encapsulation layer 171 have been eliminated, the first sub-through hole H1 and the second sub-through hole H2 may be formed. The first sub-through hole H1 may penetrate the substrate 110 and the second sub-through hole H2 may penetrate the transistor layer 130, the display element layer 150 and the encapsulation layer 170. In addition, by removing the dummy substrate 111, a part of the substrate cover layer 400 on the dummy substrate 111 may be removed, such that a dummy hole DH may be formed. The dummy hole DH may penetrate the substrate cover layer 400. The dummy hole DH may be in line with the first sub-through hole H1 and the second sub-through hole H2. In the plan view as shown in FIG. 20, the circumference (or inner wall) of the first sub-through hole H1 may surround the dummy hole DH.

Subsequently, as shown in FIG. 21, a process of trimming the substrate cover layer 400 in the vicinity of the dummy hole DH may be performed. For example, a portion of the substrate cover layer 400 that overlaps with the first sub-through hole H1 may be removed by a laser beam LB2. Accordingly, as shown in FIG. 22, a third sub-through hole H3 penetrating the substrate cover layer 400 may be formed. Then, a through hole TH including the first sub-through hole H1, the second sub-through hole H2 and the third sub-through hole H3 may be formed. In the plan view as shown in FIG. 23, the circumference (or inner wall) of the third sub-through hole H3 may surround the first sub-through hole H1 and the second sub-through hole H2.

According to the method for fabricating a display device 10 according to some embodiments of the present disclosure, as shown in FIG. 18, the substrate cover layer 400 is formed with a uniform thickness on the entire surface of the substrate 110 and the dummy substrate 111 and then the through hole TH is formed. Therefore, even after the through hole TH is formed, the thickness of the portion of the substrate cover layer 400 around the through hole TH can be equal (or substantially equal) to the thickness of the other portions of the substrate cover layer 400.

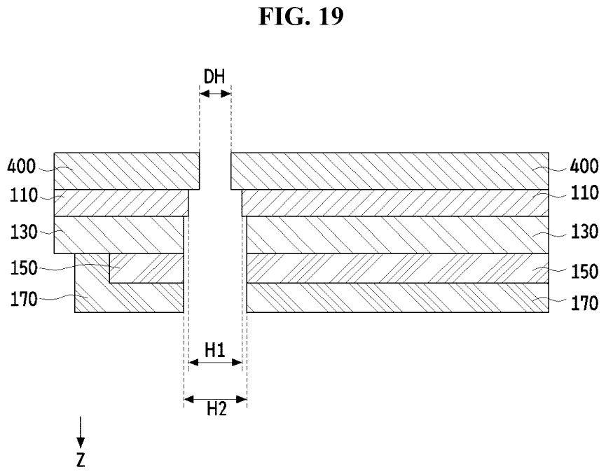

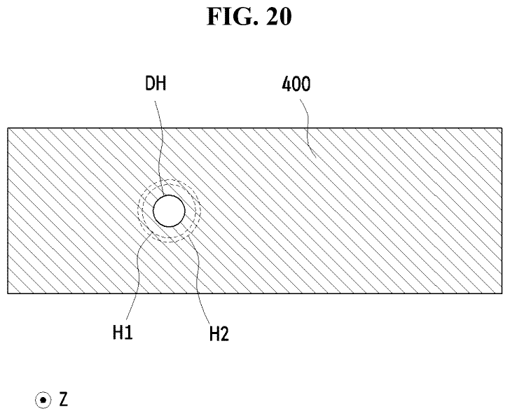

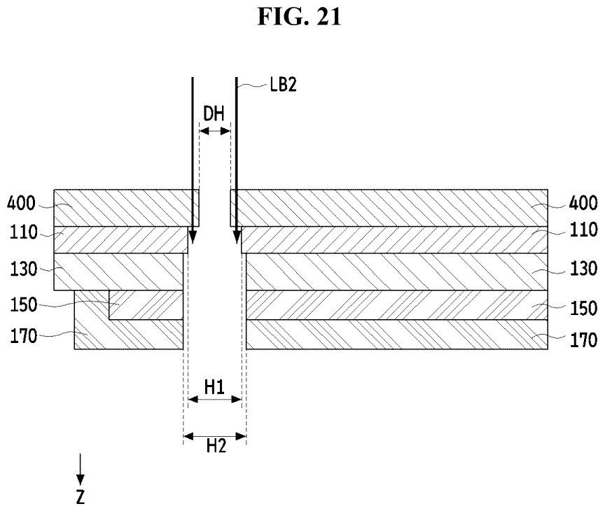

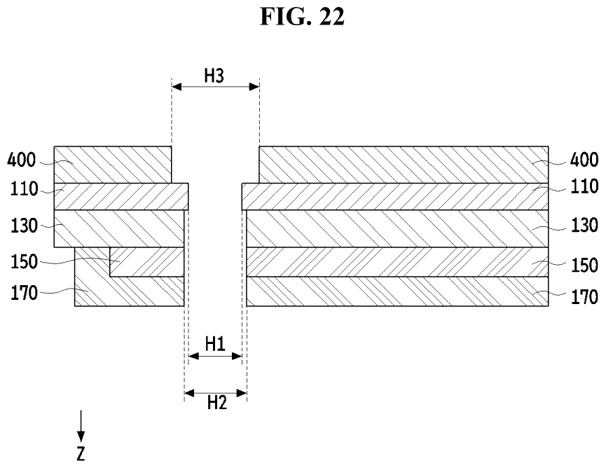

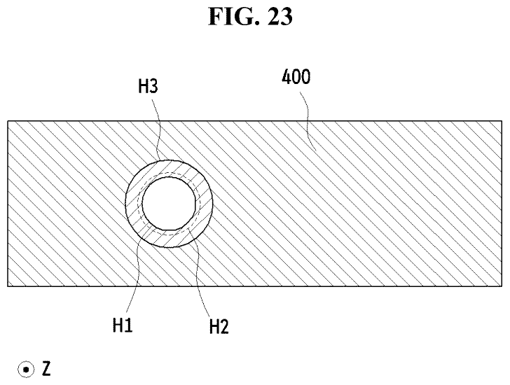

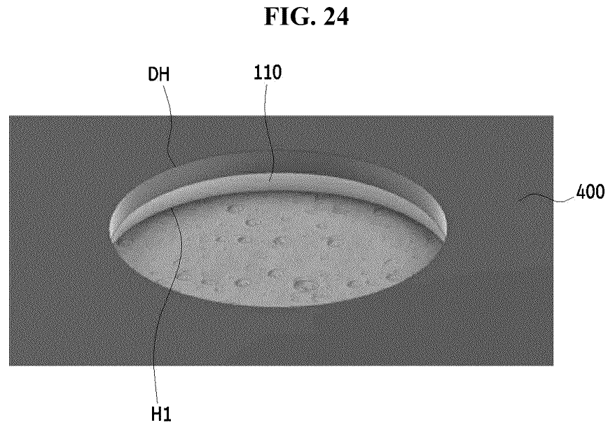

FIG. 24 is a view showing a dummy hole DH, a first sub-through hole H1, a substrate 110, and a substrate cover layer 400 according to some embodiments. For example, FIG. 24 may be a perspective view of the substrate cover layer shown in FIG. 20.

As shown in FIG. 24, the dummy hole DH may be in line with the first sub-through hole. When viewed from the top, the circumference (or inner wall) of the first sub-through hole H1 may surround the dummy hole DH.

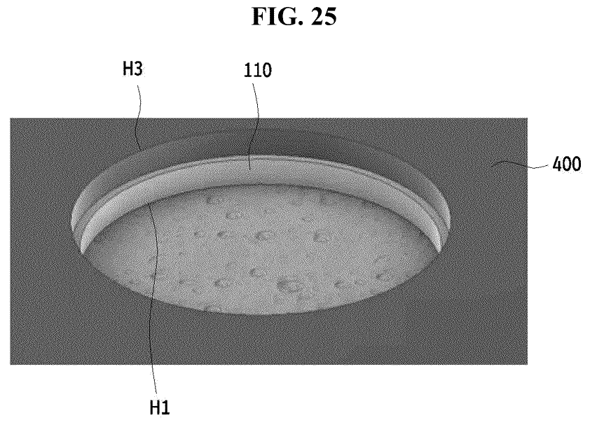

FIG. 25 is a view showing a third sub-through hole H3, a first sub-through hole H1, a substrate 110, and a substrate cover layer 400 according to some embodiments. For example, FIG. 24 may be a perspective view of that shown in FIG. 23.

As shown in FIG. 25, the third sub-through hole H3 may overlap with the first sub-through hole. When viewed from the top, the circumference (or inner wall) of the third sub-through hole H3 may surround the first sub-through hole H1.

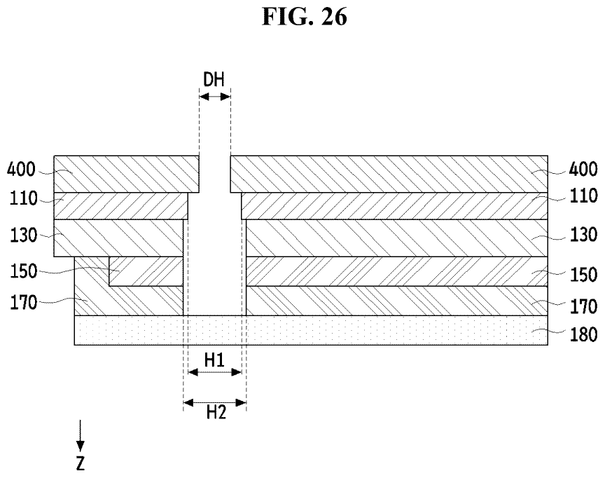

FIGS. 26 to 28 are cross-sectional views showing processing steps for illustrating a method for fabricating a display device 10 according to some embodiments of the present disclosure.

The method for fabricating the display device 10 shown in FIGS. 26 to 28 is associated with the method for fabricating the display device 10 after the step shown in FIG. 19 described above. Therefore, the description of the processing steps prior to FIGS. 26 to 28 is identical to that of FIGS. 13 to 19 and thus will not be repeated.

After the step of FIG. 19, a polarizing plate 180 may be formed on the encapsulation layer 170, as shown in FIG. 26. The polarizing plate 180 may overlap with the dummy hole DH, the first sub-through hole H1, and the second sub-through hole H2.

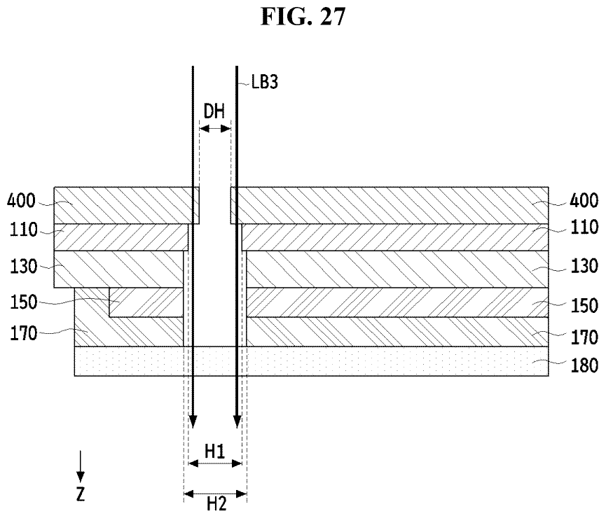

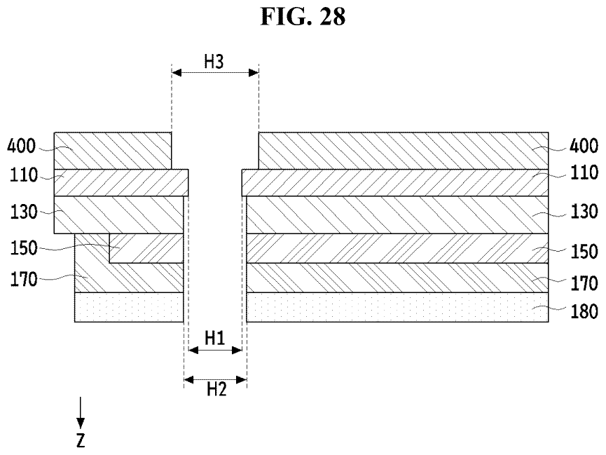

Subsequently, as shown in FIG. 27, a process of trimming the substrate cover layer 400 in the vicinity of the dummy hole DH may be performed. For example, a portion of the substrate cover layer 400 that overlaps with the first sub-through hole H1 may be removed by a laser beam LB3. Then, as shown in FIG. 28, a second sub-through hole H2 penetrating the polarizing plate 180, the encapsulation layer 170, the display element layer 150 and the transistor layer 130 may be formed, and a third sub-through hole H3 penetrating the substrate cover layer 400 may be formed.

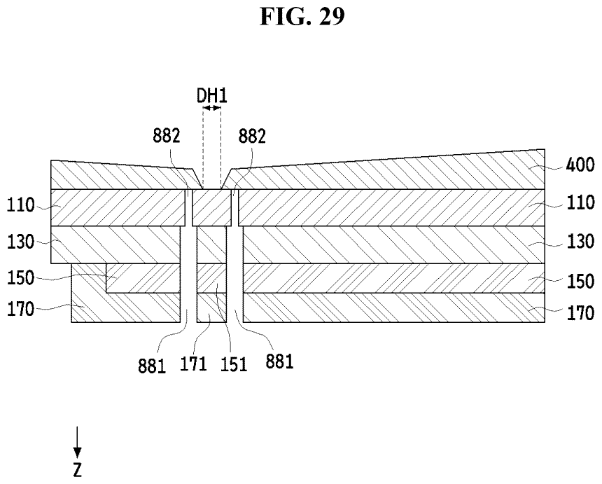

FIGS. 29 to 32 are cross-sectional views showing processing steps for illustrating a method for fabricating a display device 10 according to some embodiments of the present disclosure. For example, FIGS. 29 to 31 may be process cross-sectional views for fabricating the display device 10 of FIG. 6 described above.

The method for fabricating the display device 10 shown in FIGS. 29 to 32 is associated with the method for fabricating the display device 10 after the step shown in FIG. 17 described above. Therefore, the description of the processing steps prior to FIGS. 29 to 32 is identical to that of FIGS. 13 to 17 and thus will not be repeated.

After the step of FIG. 17, as shown in FIG. 29, a substrate cover layer 400 may be formed on the lower surfaces of the substrate 110 and the dummy substrate 111 to protect the lower surface of the etched substrate 110. For example, the substrate cover layer 400 may be formed by applying a raw material (e.g., resin) of the substrate cover layer 400 on the lower surfaces of the substrate 110 and the dummy substrate 111 by inkjet printing and then curing it. In doing so, the substrate cover layer 400 may be formed on the entire substrate 110 but not at the center of the dummy substrate 111. For example, the substrate cover layer 400 may be formed on the entire substrate 110 and the edge of the dummy substrate 111 to cover the second cut holes 882. In other words, the substrate cover layer 400 may have a first dummy hole DH1 that exposes the center of the dummy substrate 111.

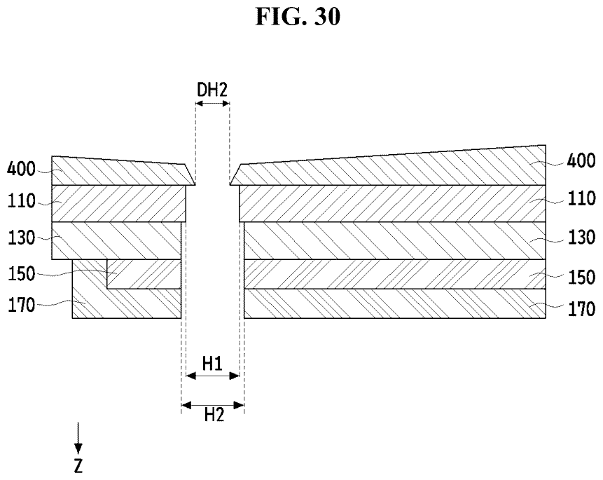

Subsequently, as shown in FIG. 30, the dummy substrate 111, the dummy transistor layer 131, the dummy display element layer 151 and the dummy encapsulation layer 171 may be eliminated. For example, the dummy substrate 111, the dummy transistor layer 131, the dummy display element layer 151 and the dummy encapsulation layer 171 may be removed by adsorbing the dummy transistor layer 131, the dummy display element layer 151 and the dummy encapsulation layer 171 using an adsorption device. After the dummy substrate 111, the dummy transistor layer 131, the dummy display element layer 151 and the dummy encapsulation layer 171 are eliminated, the first sub-through hole H1 and the second sub-through hole H2 may be formed. The first sub-through hole H1 may penetrate the substrate 110and the second sub-through hole H2 may penetrate the transistor layer 130, the display element layer 150 and the encapsulation layer 170. In addition, by removing the dummy substrate 111, a part of the substrate cover layer 400 on the dummy substrate 111 may be removed, such that a second dummy hole DH2 may be formed. The second dummy hole DH2 may penetrate the substrate cover layer 400. The diameter of the second dummy hole DH2 may be larger than the diameter of the first dummy hole DH1. The second dummy hole DH2 may be in line with the first sub-through hole H1 and the second sub-through hole H2. In the plan view as shown in FIG. 20, the circumference (or inner wall) of the first sub-through hole H1 may surround the second dummy hole DH2.

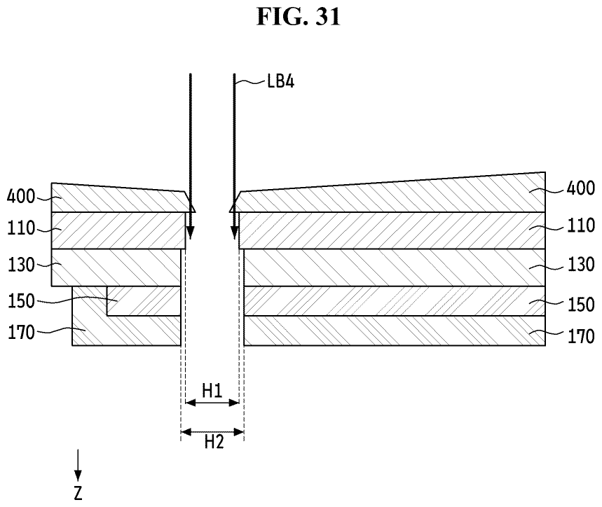

Subsequently, as shown in FIG. 31, a process of trimming the substrate cover layer 400 in the vicinity of the second dummy hole DH2 may be performed.

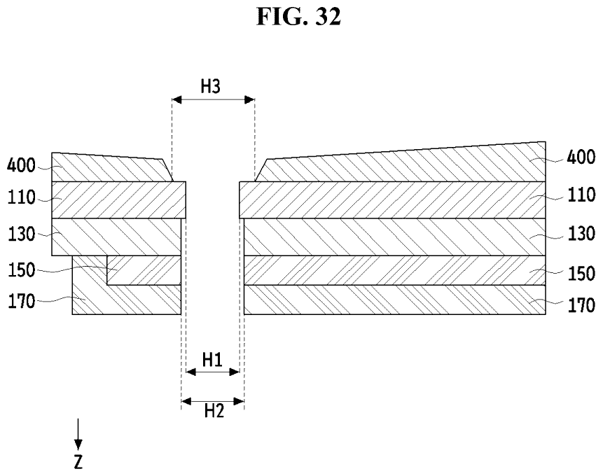

For example, a portion of the substrate cover layer 400 that overlaps with the first sub-through hole H1 may be removed by a laser beam LB4. Accordingly, as shown in FIG. 32, a third sub-through hole H3 penetrating the substrate cover layer 400 may be formed. Then, a through hole TH including the first sub-through hole H1, the second sub-through hole H2 and the third sub-through hole H3 may be formed. In the plan view as shown in FIG. 32, the circumference (or inner wall) of the third sub-through hole H3 may surround the first sub-through hole H1 and the second sub-through hole H2.

According to the method for fabricating the display device 10 shown in FIGS. 29 to 32, because the substrate cover layer 400 applied on the substrate 110 and the dummy substrate 111 has the first dummy hole DH1, the contact area between the substrate cover layer 400 and the dummy substrate 111 can be reduced as shown in FIG. 29. Accordingly, the dummy substrate 111, the dummy transistor layer 131, the dummy display element layer 151 and the dummy encapsulation layer 171 can be removed more easily as shown in FIG. 30.

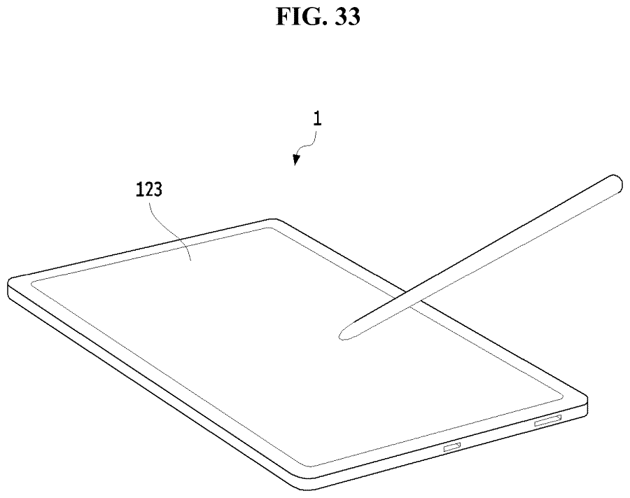

FIG. 33 is a perspective view showing an electronic device employing a display device according to some embodiments.

Referring to FIG. 33, a tablet device 1 employing a display device 123 according to some embodiments is shown as an example of an electronic device. It should be noted that the display device 123 according to some embodiments may be applied to other electronic devices in addition to the tablet device 1. For example, the display device 123 according to some embodiments may be applied to an electronic device displaying moving images or still images. For example, the display device 123 according to some embodiments may be employed by portable electronic devices such as a mobile phone, a smart phone, a smart watch, a watch phone, a mobile communications terminal, an electronic notebook, an electronic book, a portable multimedia player (PMP), a navigation device, and a ultra mobile PC (UMPC). Alternatively, the display device 123 according to some embodiments may be used as a display screen of a variety of electronic devices such as a television, a laptop computer, a monitor, an electronic billboard, and the Internet of Things (IOT).

The display device 123 of FIG. 33 may be, for example, identical to the display device 10 of FIGS. 1 to 32 described above.

The display device according to some embodiments can be applied to various electronic devices. The electronic device according to some embodiments includes the display device described above and may further include modules or devices having additional functions in addition to the display device.

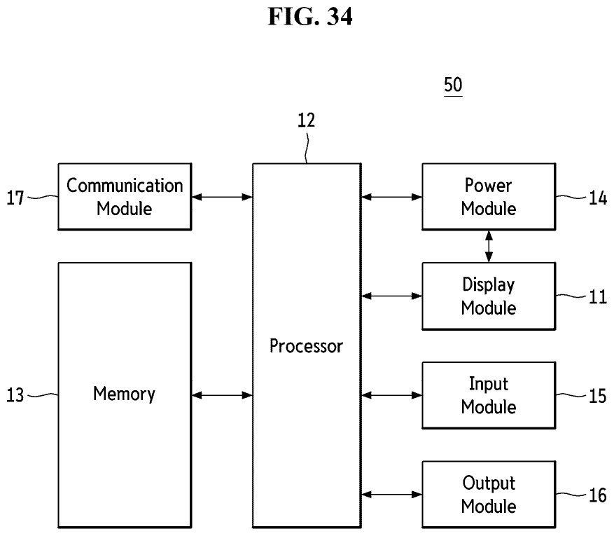

FIG. 34 is a block diagram of an electronic device according to some embodiments. Referring to FIG. 34, the electronic device 50 according to some embodiments may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

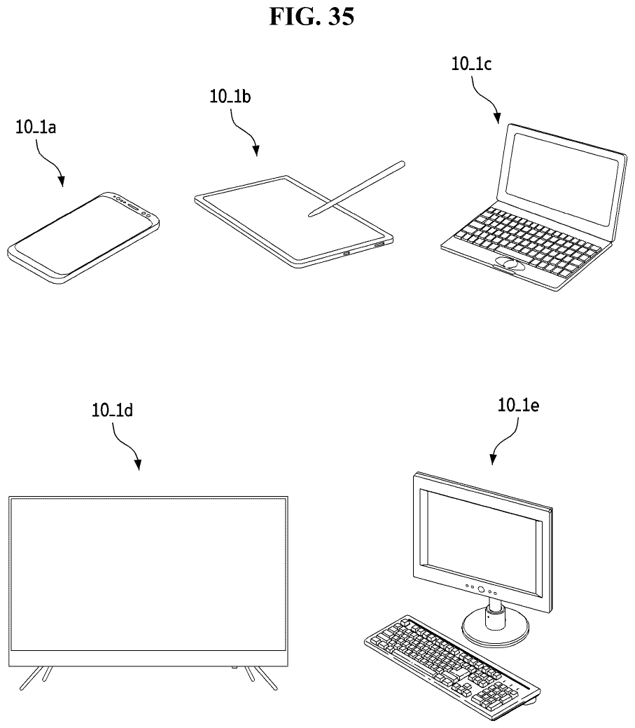

FIGS. 35, 36, and 37 are schematic diagrams of electronic devices according to various embodiments. FIGS. 35 to 37 illustrate examples of various electronic devices to which the display device according to the embodiments is applied.

FIG. 35 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

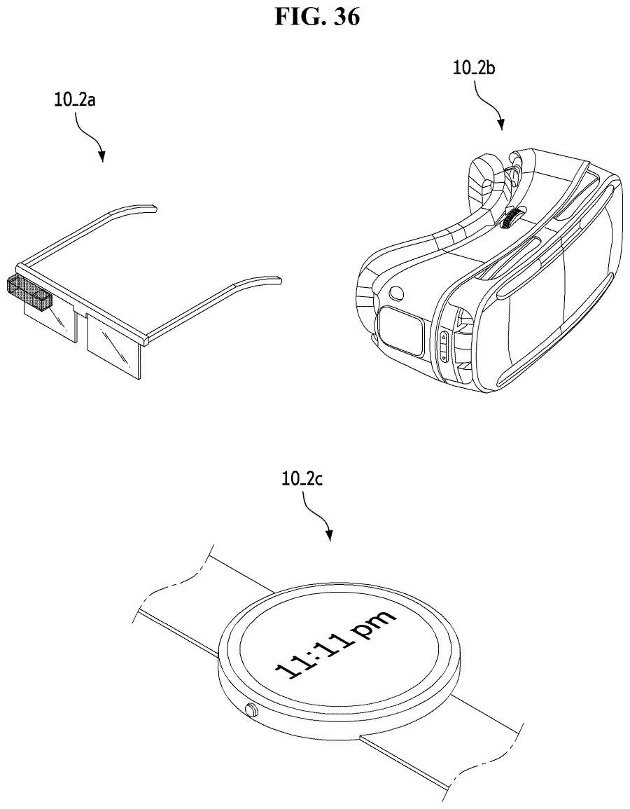

FIG. 36 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

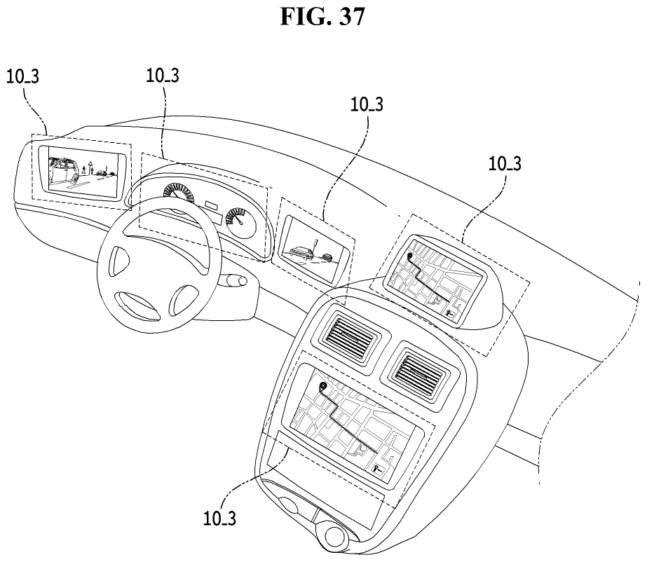

The smart watch 10_2c includes a biometric sensor as an input device, and may provide biometric information recognized by the biometric sensor to the user through the display module. FIG. 37 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

In concluding the detailed description, those skilled in the art will appreciate that many variations and modifications can be made to the disclosed embodiments without departing from the spirit and scope of embodiments according to the present invention. Therefore, the disclosed embodiments of the invention are used in a generic and descriptive sense only and not for purposes of limitation.

What is claimed is:

1. A display device comprising:
a substrate;
a transistor layer on an upper surface of the substrate;
a display element layer on the transistor layer;
an encapsulation layer on the display element layer;
a polarizing layer on the encapsulation layer;
a substrate cover layer on a lower surface of the substrate; and
a through hole penetrating the substrate cover layer, the substrate, the transistor layer, the display element layer, the encapsulation layer, and the polarizing layer in a display area of the substrate,
wherein a thickness of the substrate cover layer is constant throughout an entire area of the substrate cover layer.

2. The display device of claim 1, wherein the substrate cover layer comprises:
an upper surface contacts the lower surface of the substrate;
a lower surface opposite the upper surface of the substrate cover layer; and
an inner surface defining an inner wall of the through hole.

3. The display device of claim 2, wherein the upper surface of the substrate cover layer and the lower surface of the substrate cover layer are parallel to each other.

4. The display device of claim 2, wherein an internal angle between the upper surface of the substrate cover layer and the inner surface of the substrate cover layer is 90 degrees, and an internal angle between the lower surface of the substrate cover layer and the inner surface of the substrate cover layer is 90 degrees.

5. The display device of claim 1, wherein the through hole comprises a plurality of sub-through holes having different diameters.

6. The display device of claim 5, wherein the through hole comprises:
a first sub-through hole penetrating the substrate;
a second sub-through hole having a diameter larger than that of the first sub-through hole and penetrating the transistor layer, the display element layer, the encapsulation layer and the polarizing layer; and
a third sub-through hole having a diameter larger than that of the second sub-through hole and penetrating the substrate cover layer.

7. The display device of claim 6, wherein the second sub-through hole surrounds the first sub-through hole in a plan view.

8. The display device of claim 6, wherein the third sub-through hole surrounds the first sub-through hole and the second sub-through hole in a plan view.

9. The display device of claim 5, wherein the through hole comprises:
a first sub-through hole penetrating the substrate cover layer and the substrate; and
a second sub-through hole having a diameter larger than that of the first sub-through hole and penetrating the transistor layer, the display element layer, the encapsulation layer and the polarizing layer.

10. The display device of claim 9, wherein the second sub-through hole surrounds the first sub-through hole in a plan view.

11. The display device of claim 1, further comprising: a functional layer on the lower surface of the substrate cover layer.

12. The display device of claim 11, wherein the through hole further penetrates the functional layer in the display area of the substrate.

13. The display device of claim 12, wherein the through hole comprises:
a first sub-through hole penetrating the substrate;
a second sub-through hole having a diameter larger than that of the first sub-through hole and penetrating the transistor layer, the display element layer, the encapsulation layer, and the polarizing layer;
a third sub-through hole having a diameter larger than that of the second sub-through hole and penetrating the substrate cover layer; and
a fourth sub-through hole having a diameter larger than that of the third sub-through hole and penetrating the functional layer.

14. The display device of claim 1, further comprising:
an optical module inserted into the through hole.

15. A display device comprising:
a substrate;
a transistor layer on an upper surface of the substrate;
a display element layer on the transistor layer;
an encapsulation layer on the display element layer;
a polarizing layer on the encapsulation layer;
a substrate cover layer on a lower surface of the substrate; and
a through hole penetrating the substrate cover layer, the substrate, the transistor layer, the display element layer, the encapsulation layer, and the polarizing layer in a display area of the substrate,
wherein the substrate cover layer comprises:
an upper surface contacting the lower surface of the substrate;
a lower surface opposite the upper surface of the substrate cover layer; and
an inner surface defining an inner wall of the through hole, and
wherein an inclination of the inner surface of the substrate cover layer is different from an inclination of the lower surface of the substrate cover layer.

16. The display device of claim 15, wherein the inclination of the inner surface of the substrate cover layer is greater than the inclination of the lower surface of the substrate cover layer.

17. The display device of claim 15, wherein the through hole comprises a plurality of sub-through holes having different diameters.

18. The display device of claim 17, wherein the through hole comprises:
a first sub-through hole penetrating the substrate;
a second sub-through hole having a diameter larger than that of the first sub-through hole and penetrating the transistor layer, the display element layer, the encapsulation layer and the polarizing layer; and
a third sub-through hole having a diameter larger than that of the second sub-through hole and penetrating the substrate cover layer.

19. The display device of claim 18, wherein the second sub-through hole surrounds the first sub-through hole in a plan view.

20. An electronic device comprising:
a display device providing a screen, wherein the display device comprising:
a substrate;
a transistor layer on an upper surface of the substrate;
a display element layer on the transistor layer;
an encapsulation layer on the display element layer;
a polarizing layer on the encapsulation layer;
a substrate cover layer on a lower surface of the substrate; and
a through hole penetrating the substrate cover layer, the substrate, the transistor layer, the display element layer, the encapsulation layer, and the polarizing layer in a display area of the substrate, and
wherein a thickness of the substrate cover layer is constant throughout an entire area of the substrate cover layer.
